(19) United States
(12) Patent Application Publication
(10) Pub. No.: US 2008/0211041 A1
(43) Pub. Date: Sep. 4, 2008

(54) Micro electrical mechanical system device

(75) Inventor: Akihiko Nomura, Miyazaki (JP)

Correspondence Address: TAKEUCHI & KUBOTERA, LLP, SUITE 202, 200 DAINGERFIELD ROAD, ALEXANDRIA, VA, 22314, US

(73) Assignee: Oki Electric Industry Co., Ltd, Miyazaki Oki Electric Industry Co., Ltd.

(21) Appl. No.: 11/783,809

(22) Filed: Apr. 12, 2007

(30) Foreign Application Priority Data
May 31, 2006 (JP) 2006-150916

(51) Int. Cl. H01L 29/84

(52) U.S. Cl. 257/415; 257/E29.324

(57) ABSTRACT

A micro electrical mechanical system device includes a frame portion having an upper surface with a rectangular shape; a functional element; a beam portion extending from one of sides of the frame portion toward an opposite one and having a first side surface, a second side surface opposite to the first side surface, and upper and lower surfaces between the first and second side surfaces; and a movable portion supported on the beam portion inside the frame portion to be movable. The beam portion includes a constricted portion formed in the first side surface and the second side surface along the functional element, and having a main surface and two side surfaces facing each other. The movable portion includes a center portion having four corner portions and protruding portions extending from the corner portions and away from the frame portion and the beam portion.

### BACKGROUND OF THE INVENTION AND RELATED ART STATEMENT

The present invention relates to a micro electrical mechanical system device.

Recently, technology for producing a microstructure having a size of a few hundred microns has been advanced using micro-machining technology based on semiconductor manufacturing technology. The technology has been applied to, for example, various sensors, photo-switches in an optical communication system, and radio frequency (RF) components. Since such a microstructure can be produced with a conventional semiconductor manufacturing process, it is possible to mount a large number of microstructures on a single chip combined with, for example, a signal processing type large scale integrated circuit (LSI).

Such a chip formed of the microstructures having a system with a specific function is called Micro-Electrical-Mechanical-Systems (MEMS) or Micro-System-Technology (MIST) (referred to as an MEMS device hereinafter).

The MEMS device includes a semiconductor acceleration sensor having a beam portion fixed to a frame portion and a weight portion supported on the beam portion. The weight portion is called a movable portion capable of moving upon receiving an external force. The movable portion is integrated with the beam portion as the microstructure.

In the semiconductor acceleration sensor, in order to improve detection sensitivity, it has been tried to, for example, increase a mass of the weight portion or reduce rigidity of the beam portion.

For example, Patent Reference has disclosed a semiconductor acceleration sensor, in which a beam portion has a width at a part thereof continuously or intermittently widened adjacent to a connecting portion connected to one or both of a weight portion and a frame portion. Accordingly, it is possible to improve impact resistance as well as detection sensitivity. Patent Reference: Japanese Patent Publication No. 2004-177357

In the semiconductor acceleration sensor described above, in order to improve detection sensitivity, it is necessary to drastically change a design of the acceleration sensor in order to increase a mass of the weight portion or change a width or thickness of the beam portion, thereby increasing production cost thereof.

In view of the problems described above, an object of the present invention is to provide a micro electrical mechanical system device, in which it is possible to improve detection sensitivity without implementing drastic design change in a movable portion thereof.

Further objects and advantages of the invention will be apparent from the following description of the invention.

### SUMMARY OF THE INVENTION

In order to attain the objects described above, according to the present invention, a micro electrical mechanical system device includes a frame portion having an upper surface with a rectangular shape; a functional element; a beam portion extending from one of sides of the frame portion toward an opposite one of the sides and having a first side surface, a second side surface opposite to the first side surface, and upper and lower surfaces between the first side surface and the second side surface; and a movable portion supported on the beam portion inside the frame portion to be movable.

The beam portion further includes a constricted portion formed in the first side surface and the second side surface along the functional element, and having a main surface and two side surfaces facing each other between the upper surface and the lower surface. The movable portion includes a center portion having four corner portions and protruding portions extending from the four corner portions and away from the frame portion and the beam portion.

In the present invention, the beam portion includes the constricted portion formed in the first side surface and the second side surface along the functional element. Accordingly, it is possible to improve detection sensitivity of the MEMS device without implementing drastic design change in the movable portion thereof such as a length, a width, and a mass thereof.

### BRIEF DESCRIPTION OF THE DRAWINGS

FIG. 1(A) is a schematic plan view showing a micro electrical mechanical system device such as a semiconductor acceleration sensor according to an embodiment of the present invention, FIG. 1(B) is a sectional view taken along a projected line 1(B)-1(B) in FIG. 1(A), and FIG. 1(C) is a sectional view taken along a projected line 1(C)-1(C) in FIG. 1(A);

FIG. 2 is a schematic plan view showing the semiconductor acceleration sensor viewed from a backside surface thereof according to the embodiment of the present invention;

FIG. 3(A) is a schematic enlarged view of an area 3 in FIG. 1(A) showing an example No. 1 of a constricted portion, FIG. 3(B) is a schematic enlarged view of the area 3 in FIG. 1(A) showing an example No. 2 of the constricted portion, and FIG. 3(C) is a schematic enlarged view of the area 3 in FIG. 1(A) showing an example No. 3 of the constricted portion;

FIGS. 4(A) to 4(C) are schematic sectional views showing the semiconductor acceleration sensor during a manufacturing process thereof and taken along the projected line 1(B)-1(B) in FIG. 1(A);

FIGS. 5(A) to 5(C) are schematic sectional views showing the semiconductor acceleration sensor during the manufacturing process thereof continued from FIG. 4(C) and taken along the projected line 1(B)-1(B) in FIG. 1(A);

FIGS. 6(A) to 6(D) are schematic sectional views showing the semiconductor acceleration sensor during the manufacturing process thereof continued from FIG. 5(C), wherein FIG. 6(A) is taken along the projected line 1(B)-1(B) in FIG. 1(A), FIG. 6(B) is taken along the projected line 1(B)-1(B) in FIG. 1(A), FIG. 6(C) is taken along the projected line 1(C)-1(C) in FIG. 1(A) at a moment same as that of FIG. 6(B), and FIG. 6(D) is taken along the projected line 1(B)-1(B) in FIG. 1(A); and

FIGS. 7(A) to 7(D) are schematic sectional views showing the semiconductor acceleration sensor during the manufacturing process thereof continued from FIG. 6(D), wherein FIG. 7(A) is taken along the projected line 1(B)-1(B) in FIG. 1(A), FIG. 7(B) is taken along the projected line 1(C)-1(C) in FIG. 1(A) at a moment same as that of FIG. 7(A), and FIG. 7(C) is taken along the projected line 1(B)-1(B) in FIG. 1(A).

### DETAILED DESCRIPTION OF PREFERRED EMBODIMENTS

Hereunder, embodiments of the present invention will be explained with reference to the accompanying drawings. The drawings schematically show shapes, sizes, and positional relationships of constituents, and the invention is not limited to those shown in the drawings. In the drawings, a size, a shape, and an arrangement of constituting components are schematically shown for explanation of the present invention. Specific materials, conditions, and numerical conditions described in the following description are just examples. In the following description, same reference numerals denote similar components, and explanations thereof may be omitted.

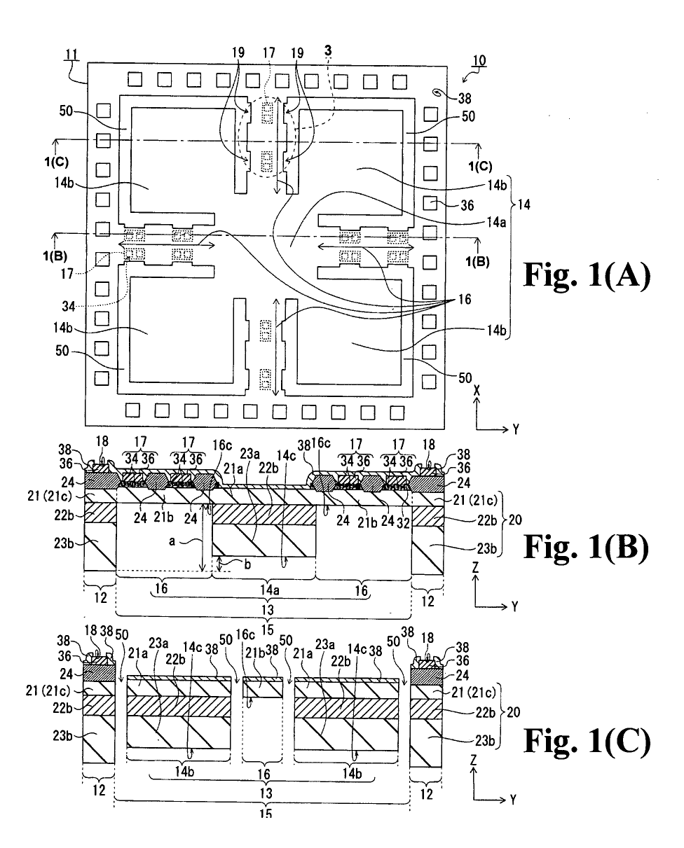

A configuration of a micro electrical mechanical system (MEMS) device according to an embodiment of the present invention will be explained with reference to FIGS. 1(A) to 1(C), 2, and 3(A) to 3(B). In the embodiment, the micro electrical mechanical system device includes a piezo-type three-axial semiconductor acceleration sensor chip with a piezo-element. The semiconductor acceleration sensor chip is a semiconductor element capable of measuring specific acceleration.

FIG. 1(A) is a schematic plan view showing the semiconductor acceleration sensor viewed from a front surface thereof according to the embodiment of the present invention, FIG. 1(B) is a sectional view taken along a projected line 1(B)-1(B) in FIG. 1(A), and FIG. 1(C) is a sectional view taken along a projected line 1(C)-1(C) in FIG. 1(A).

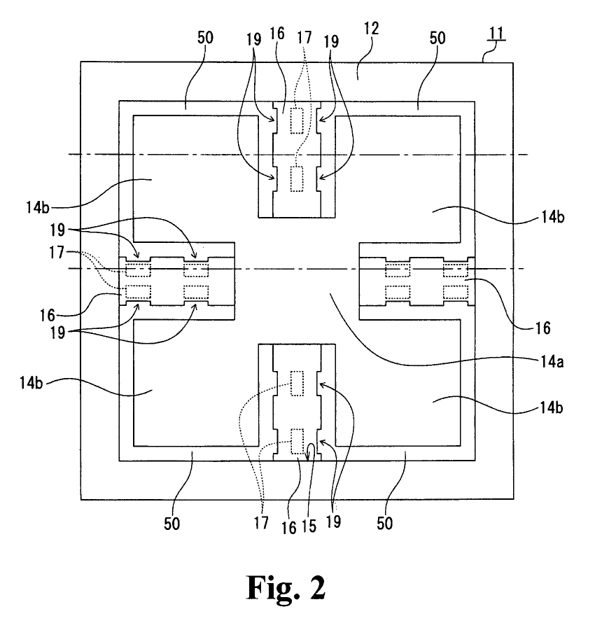

FIG. 2 is a schematic plan view showing the semiconductor acceleration sensor viewed from a backside surface thereof according to the embodiment of the present invention.

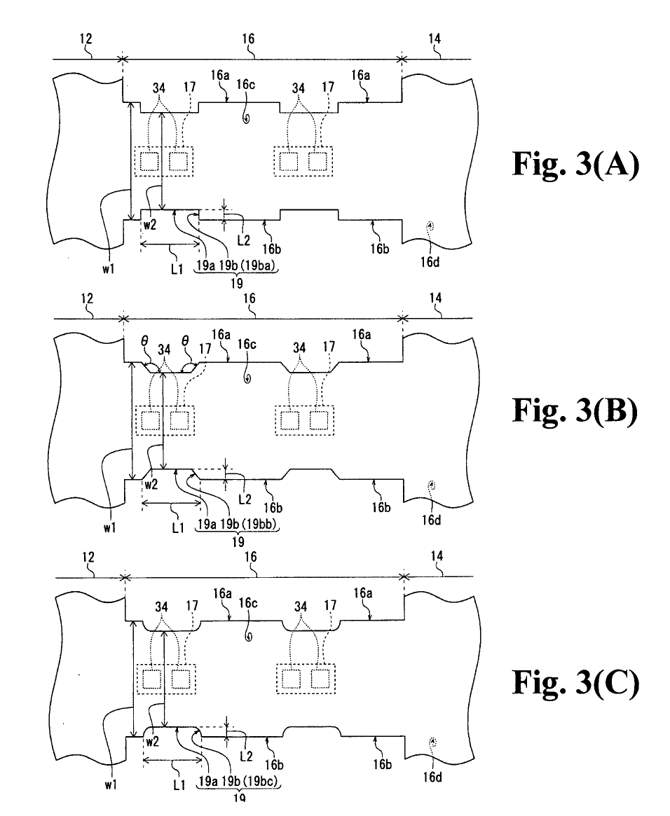

FIG. 3(A) is a schematic enlarged view of an area 3 in FIG. 1(A) showing an example No. 1 of a constricted portion, FIG. 3(B) is a schematic enlarged view of the area 3 in FIG. 1(A) showing an example No. 2 of the constricted portion, and FIG. 3(C) is a schematic enlarged view of the area 3 in FIG. 1(A) showing an example No. 3 of the constricted portion.

According to the embodiment of the present invention, the semiconductor acceleration sensor or acceleration sensor includes the constricted portion for improving detection sensitivity.

In the embodiment, a semiconductor acceleration sensor 10 is integrated in a chip 11 having a rectangular shape in a plan view viewed from a front surface and a backside surface thereof. A frame portion 12 is provided at a circumferential edge of the backside surface of the chip 11. A recess portion 15 is formed inside the frame portion 12 of the chip 11.

In the embodiment, the semiconductor acceleration sensor 10 further includes a movable portion or weight portion 14 and a microstructure 13 having beam portions 16. The microstructure 13 includes a first semiconductor layer 21 commonly shared in the movable portion 14 and the beam portions 16. The first semiconductor layer 21 is formed of silicon and also called a first silicon layer 21.

In the embodiment, in a partial area of the backside surface of the first silicon layer 21 of the semiconductor acceleration sensor 10, the movable portion 14 includes a sacrifice layer portion 22b and a second semiconductor layer portion 23a formed under the sacrifice layer portion 22b. The second semiconductor layer portion 23a is formed of silicon and also called a second silicon layer portion 23a. Further, under the first silicon layer 21, the frame portion 12 includes the sacrifice layer portion 22b and the second silicon layer portion 23a formed under the sacrifice layer portion 22b.

Accordingly, the movable portion 14 and the beam portions 16 are partially integrated through the first silicon layer 21, and the frame portion 12 and the beam portions 16 are partially integrated through the first silicon layer 21. With the first silicon layer 21, the frame portion 12 supports the beam portions 16, and the beam portions 16 support the movable portion 14.

In the semiconductor acceleration sensor 10, it is necessary to configure such that the movable portion 14 is movable with an external force applied thereto. To this end, spaces 50 are formed between the movable portion 14 and the frame portion 12, and between side edges of the beam portions 16 and the movable portion 14 except portions of the beam portions 16 connected to the frame portion 12 and the movable portion 14. Accordingly, the movable portion 14 is not directly connected to the frame portion 12, and the beam portions 16 do not interfere a movement of the movable portion 14. The spaces 50 extend from the front surface of the semiconductor acceleration sensor 10 up to the recess portion 15 through the first silicon layer 21.

As described above, the movable portion 14 includes a portion 21a of the first silicon layer 21, the sacrifice layer portion 22b, and the second silicon layer portion 23a. Further, the beam portions 16 include the first semiconductor layer portion 21a, and do not include the sacrifice layer portion 22b and the second silicon layer portion 23a. Accordingly, in the movable portion 14, the sacrifice layer portion 22b and the second silicon layer portion 23a function as a weight for providing inertia relative to the movement of the movable portion 14.

In the embodiment, the beam portions 16 have an elongated thin plate shape, so that the beam portions 16 deform when the movable portion 14 moves. A bottom surface of the recess portion 15 includes exposed surfaces 16c of the first semiconductor layer portion 21a and exposed surfaces 14c of the second silicon layer portion 23a. The exposed surfaces 16c are situated at a first depth a from the front surface of the frame portion 12. The exposed surfaces 14c are situated at a second depth b from the front surface of the frame portion 12 smaller than the first depth a.

As shown in FIGS. 1(A) to 1(C) and 2, four of the beam portions 16 extend inside from centers of sides of the frame portion 12 having a square shape. In each of the beam portions 16, a distal end thereof supports a center portion 14a of the movable portion 14. The center portion 14a of the movable portion 14 has a rectangular shape in a plan view, and the beam portions 16 are connected to centers of sides of the rectangular shape.

In the embodiment, the movable portion 14 has protruding portions 14b extending toward the frame portion 12 from four corner portions of the center portion 14a at a circumference thereof. Accordingly, the beam portions 16 support the protruding portions 14b of the movable portion 14 inside the frame portion 12 to be movable, so that the protruding portions 14b do not contact with the frame portion 12 and the beam portions 16.

In the embodiment, according to a design of the semiconductor acceleration sensor 10, a certain number of functional elements such as piezo resistor elements 17 are formed on the first semiconductor layer portion 21a or the first silicon layer 21 constituting the beam portions 16. In the case that the MEMS device is the semiconductor acceleration sensor 10, the piezo resistor elements 17 are disposed at appropriate positions for measuring acceleration.

In the embodiment, contact holes 34 passing through a thermal oxidization layer 32 are embedded in each of the piezo resistor elements 17, so that a wiring 36 is connected thereto for outputting a signal externally. The wiring 36 may be formed of a well-known material such as aluminum. A passivasion layer 38 is formed on the front surface of the semiconductor acceleration sensor 10.

In the embodiment, electrode pads 18 are disposed on the frame portion 12 and electrically connected to the piezo resistor elements 17 on the beam portions 16. The electrode pads 18 are formed of portions of the wirings 36 exposed through openings formed in the passivasion layer 38. Accordingly, in the semiconductor acceleration sensor 10, the microstructure 13 including the movable portion 14 and the beam portions 16 with the piezo resistor elements 17 is disposed inside the recess portion 15. Each of the piezo resistor elements 17 is individually separated each other with a LOCOS (local oxidation of silicon) oxidation layer 24.

A configuration of the example No. 1 of the beam portions 16 will be explained next with reference to FIG. 3(A). As shown in FIG. 3(A), each of the beam portions 16 includes a first side surface 16a and a second side surface 16b opposite to the first side surface 16a. Further, each of the beam portions 16 includes an upper surface 16c and a lower surface 16d between the first side surface 16a and the second side surface 16b. It is configured that each of the beam portions 16 has a width, i.e., a width w1 of the upper surface 16c and the lower surface 16d, of about 86 μm.

In the embodiment, each of the beam portions 16 has constricted portions 19. The constricted portions 19 have a length L1 substantially equal to an extension length L1 of the piezo resistor element 17. Further, the constricted portions 19 are disposed at positions in parallel to the piezo resistor elements 17 corresponding to the extension length L1 of the piezo resistor elements 17.

The constricted portions 19 are provided at one or more than two locations. In the embodiment, the constricted portions 19 are disposed at four locations at both sides of the piezo resistor elements 17 disposed at two locations per parts of edges defining the upper surface 16ac and the lower surface 16d of each of the beam portions 16.

Note that the extension length and the locations of the constricted portions 19 are not limited to the embodiment, and may be adjusted appropriately. For example, the constricted portions 19 may have an extension length greater or smaller than that of the piezo resistor elements 17 for adjusting detection sensitivity. Further, the constricted portions 19 may be disposed at positions not corresponding to the side surfaces of the piezo resistor elements 17.

As shown in FIGS. 3(A) to 3(C), the constricted portions 19 extend from the upper surfaces 16c and the lower surfaces 16d. In other words, the constricted portions 19 are formed in the first side surfaces 16a and the second side surfaces 16b as recess portions.

Each of the constricted portions 19 has a main surface 19a as a bottom surface thereof extending from the upper surface 16c to the lower surface 16d and having a substantially rectangular shape, and perpendicular side surfaces 19ba (side surfaces 19b) adjacent to the main surface 19a and extending in a direction perpendicular to the main surface 19a. When the width w1 is 86 μm, it is preferred that the perpendicular side surfaces 19ba have a width w2 between the upper surface 16c and the lower surface 16d of about 10 μm.

A simulation was conducted in a case that the width w1 was 86 pm and the width w2 was 10 μm. Table 1 shows a result of the simulation. The simulation was conducted as a numerical analysis simulation through a finite element method while the outer circumference of the semiconductor acceleration sensor 10 was constrained and an acceleration of 1G was applied to the movable portion 14 in an X direction and a Z direction thereof, respectively (refer to FIGS. 1(A) to 1(C)).

TABLE 1

| | Detected | | Detected | |
|---|---|---|---|---|
| | potential | Increment | potential | Increment |
| | in X | in detected | in Z | in detected |
| Beam | direction | potential | direction | potential |
| portion | (mV) | (%) | (mV) | (%) |
| Without | 0.475 | 0 | 0.659 | 0 |
| constricted | | | | |
| portion | | | | |
| L2 = 10 μm | 0.618 | 30.1 | 0.867 | 31.5 |

As shown in Table 1, with the constricted portions 19, it is possible to increase the detection sensitivity in the X direction and the Z direction by more than 30%.

A configuration of the example No. 2 of the beam portions 16 will be explained next with reference to FIG. 3(B). In the example No. 2, the side surfaces 19b adjacent to the main surfaces 19a are different from those in the example No. 1. Configurations other than the side surfaces 19b (the side surfaces 19b) are same as those in the example No. 1 and designated with the same reference numerals, and explanations thereof are omitted.

As shown in FIG. 3(B), each of the constricted portions 19 has the main surface 19a as a bottom surface thereof extending from the upper surface 16c and the lower surface 16d and having a substantially rectangular shape, and inclined side surfaces 19bb adjacent to the main surface 19a and extending in an angle θ relative to the main surface 19a.

In the example No. 2, the constricted portions 19 have sides, i.e., areas opening in the first side surfaces 16a and the second side surfaces 16b, adjacent to the edges of the upper surfaces 16c and the lower surfaces 16d, and the sides have a length equal to the extension length L1 of the piezo resistor elements 17. Accordingly, the constricted portions 19 have the main surfaces 19a having an area smaller than that of the main surfaces 19a of the constricted portions 19 in the example No. 1.

In the example No. 2, when the angle θ of the inclined side surfaces 19bb relative to the main surfaces 19a increases, it is possible to improve impact resistance. Note that the angle θ may be adjusted appropriately for improving the detection sensitivity and maintaining strength of the beam portions 16 within a range not deteriorating the purpose of the invention in consideration of the whole length of the beam portions 16 and the size of the piezo resistor elements 17.

With the configuration described above, it is possible to improve the detection sensitivity. Further, it is possible to efficiently secure the strength of the beam portions 16 and improve the impact resistance.

A configuration of the example No. 3 of the beam portions 16 will be explained next with reference to FIG. 3(C). In the example No. 3, the side surfaces 19b adjacent to the main surfaces 19a are different from those in the examples No. 1 and No. 2. Configurations other than the side surfaces 19b (curved side surfaces 19bc) are same as those in the examples No. 1 and No. 2 and designated with the same reference numerals, and explanations thereof are omitted.

As shown in FIG. 3(C), each of the constricted portions 19 has the main surface 19a as a bottom surface thereof extending from the upper surface 16c and the lower surface 16d and having a substantially rectangular shape, and curved side surfaces 19bc connected to sides of the main surface 19a in a concaved shape. That is, the curved side surfaces 19bc have a curved surface having a half pipe shape.

In the example No. 3, the constricted portions 19 have sides, i.e., areas opening in the first side surfaces 16a and the second side surfaces 16b, adjacent to the edges of the upper surfaces 16c and the lower surfaces 16d, and the sides have a length equal to the extension length L1 of the piezo resistor elements 17.

In the example No. 3, when a curvature of the curved side surfaces 19bc increases, it is possible to improve the impact resistance. Note that the curvature may be adjusted appropriately for improving the detection sensitivity and maintaining strength of the beam portions 16 within a range not deteriorating the purpose of the invention in consideration of the whole length of the beam portions 16 and the size of the piezo resistor elements 17.

With the configuration described above, it is possible to improve the detection sensitivity. Further, it is possible to efficiently secure the strength of the beam portions 16 and improve the impact resistance.

An operation of the semiconductor acceleration sensor 10 will be explained next. When the semiconductor acceleration sensor 10 receives acceleration, the movable portion 14 shifts or is displaced. That is, the beam portions 16 supporting the movable portion 14 deform according to an amount of the displacement of the movable portion 14. An amount of the deformation of the beam portions 16 is measured as a change in electrical resistance of the piezo resistor elements 17 disposed on the beam portions 16. The change in the electrical resistance thus detected is output to a detection circuit outside the semiconductor acceleration sensor 10 through the electrode pads 18 electrically connected to the piezo resistor elements 17. Accordingly, the acceleration applied to the semiconductor acceleration sensor 10 is quantitatively detected.

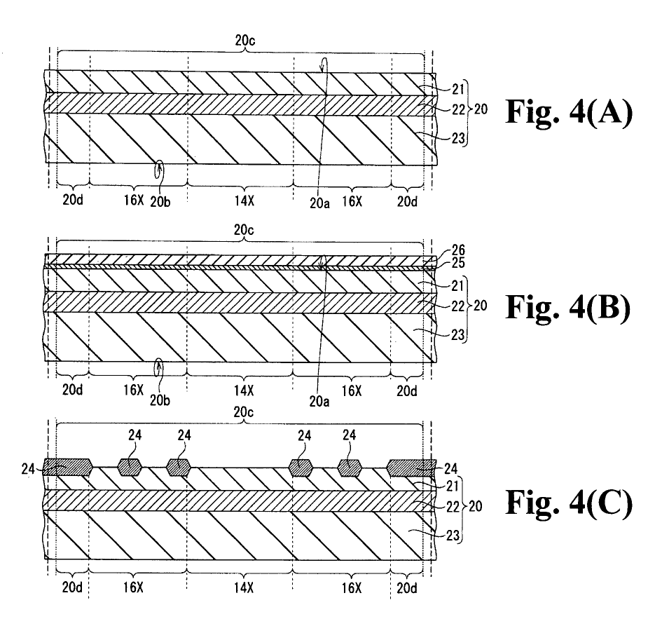

A method of producing the MEMS device will be explained next with reference to FIGS. 4(A)-4(C) to 7(A)-7(C). The MEMS device can be produced with a well-known method. In the following description, one MEMS device will be explained among a plurality of MEMS devices formed on a substrate concurrently. Further, as an example of the MEMS device, a method of producing the semiconductor acceleration sensor 10 described above will be explained.

FIGS. 4(A) to 4(C) are schematic sectional views showing the semiconductor acceleration sensor during a manufacturing process thereof and taken along the projected line 1(B)-1(B) in FIG. 1(A).

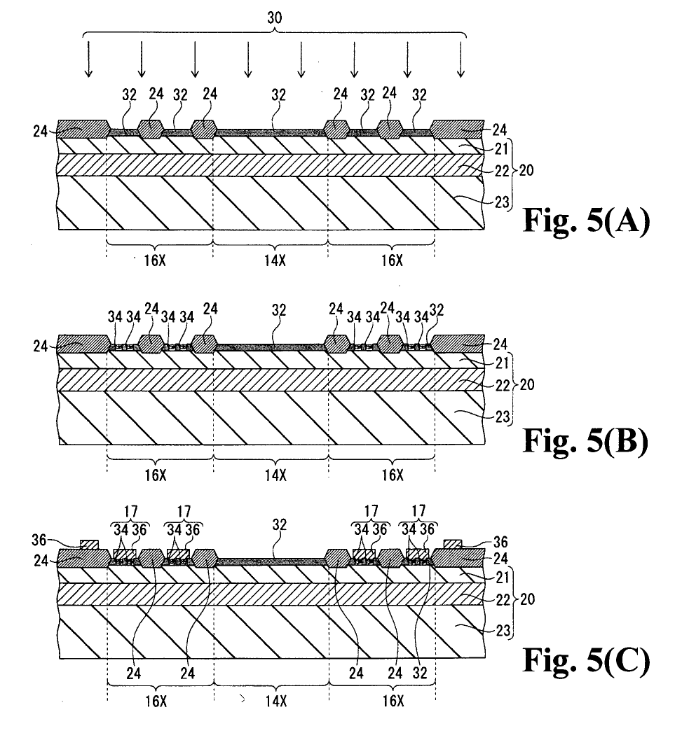

FIGS. 5(A) to 5(C) are schematic sectional views showing the semiconductor acceleration sensor during the manufacturing process thereof continued from FIG. 4(C) and taken along the projected line 1(B)-1(B) in FIG. 1(A).

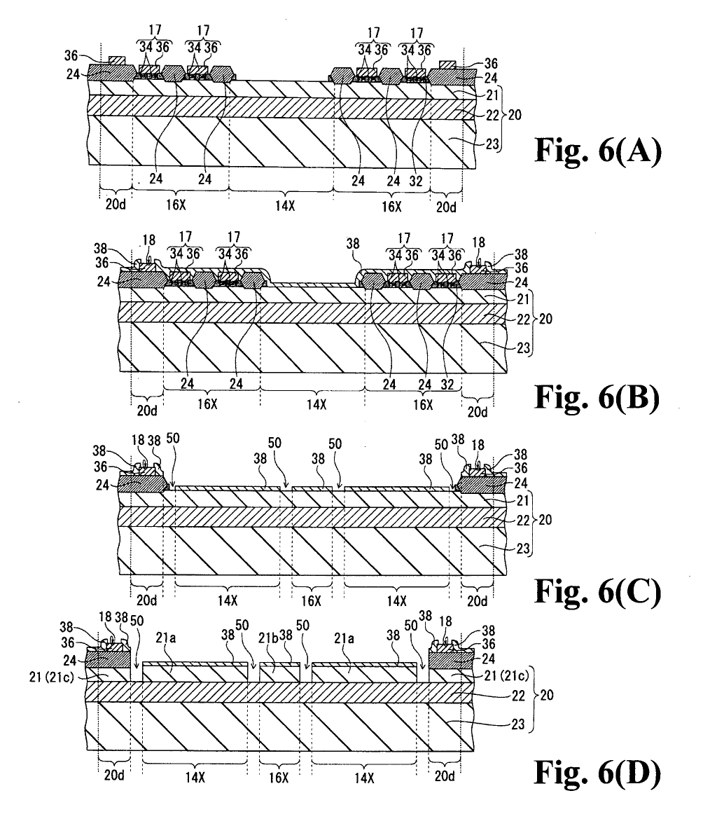

FIGS. 6(A) to 6(D) are schematic sectional views showing the semiconductor acceleration sensor during the manufacturing process thereof continued from FIG. 5(C). FIG. 6(A) is taken along the projected line 1(B)-1(B) in FIG. 1(A); FIG. 6(B) is taken along the projected line 1(B)-1(B) in FIG. 1(A); FIG. 6(C) is taken along the projected line 1(C)-1(C) in FIG. 1(A) at a moment same as that of FIG. 6(B); and FIG. 6(D) is taken along the projected line 1(B)-1(B) in FIG. 1(A).

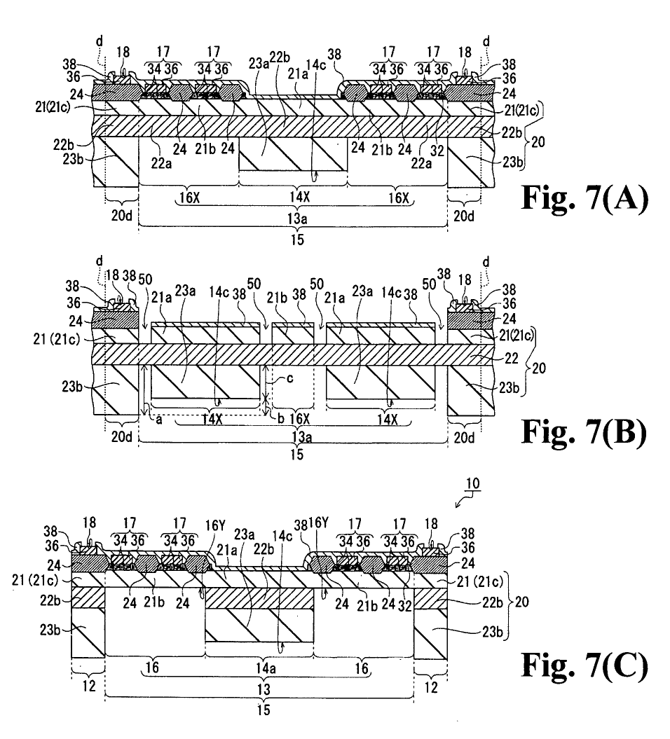

FIGS. 7(A) to 7(D) are schematic sectional views showing the semiconductor acceleration sensor during the manufacturing process thereof continued from FIG. 6(D). FIG. 7(A) is taken along the projected line 1(B)-1(B) in FIG. 1(A); FIG. 7(B) is taken along the projected line 1(C)-1(C) in FIG. 1(A) at a moment same as that of FIG. 7(A); and FIG. 7(C) is taken along the projected line 1(B)-1(B) in FIG. 1(A).

As shown in FIG. 4(A), there is provided a semiconductor substrate 20 having a first surface or a front surface 20a and a second surface or a backside surface 20b opposite to the first surface 20a. The semiconductor substrate 20 preferably includes a silicon on insulator (SOI) wafer formed of the first silicon layer 21, a sacrifice layer 22, and a second silicon layer 23 laminated therein. The semiconductor substrate 20 is not limited to the configuration, and may include a substrate having a sacrifice layer.

As shown in FIG. 4(A), a chip area 20c is defined on the semiconductor substrate 20 in advance. The chip area 20c becomes the semiconductor acceleration sensor 10 after cutting the semiconductor substrate 20 into an individual piece.

In the next step, an inner circumference frame area 20d is defined inside the chip area 20c of the semiconductor substrate 20. In the inner circumference frame area 20d, the microstructure 13 is not formed therein, and an outer shape of the semiconductor acceleration sensor 10 is formed therein later as a frame. That is, the chip area 20c includes the (inner circumference) frame area 20d wherein the frame portion 12 is formed; a movable portion forming area 14X wherein the movable portion 14 is formed; and beam portion forming areas 16X wherein the beam portions 16 are formed. The beam portion forming areas 16X include contours of the constricted portions 19 described above.

In the next step, the microstructure 13 having a primary function of the MSES device is formed. In the embodiment, the microstructure 13 includes the movable portion 14 and the beam portions 16 for supporting the movable portion 14. More specifically, as shown in FIG. 4(B), a pad oxidation layer 25 and a silicon nitride layer 26 are formed on the first silicon layer 21, i.e., the first surface 20a, of the semiconductor substrate 20 with a well-known method.

In the next step, the pad oxidation layer 25 and the silicon nitride layer 26 are patterned with a well-known photolithography process to form a specific mask pattern. The mask pattern is used for forming a local oxidation of silicon (LOCOS) layer (described later).

As shown in FIG. 4(C), LOCOS layers 24 are formed with a well-known method. The LOCOS layers 24 separate the piezo resistor elements 17 (described later). Then, the pad oxidation layer 25 and the silicon nitride layer 26 used as the mask pattern are removed.

In the next step, the piezo resistor elements 17 are formed as the functional elements with a well-known method. For example, as shown in FIG. 5(A), ions are implanted into the semiconductor substrate 20 with the LOCOS oxidation layers 24 as masks. A well-known ion implantation device may be used for the ion implantation process. More specifically, ions of a P-type impurity such as boron (B) are implanted into areas exposed from the LOCOS oxidation layers 24.

In the next step, the ions thus implanted are diffused up to portions below the LOCOS oxidation layers 24 with a well-known method through a thermal diffusion process. With the thermal diffusion process, as shown in FIG. 5(A), thermal oxidation layers 32 are formed in the areas of the semiconductor substrate 20 exposed from the LOCOS oxidation layers 24.

As described above, the piezo resistor elements 17, i.e., the functional elements for detecting acceleration, are formed at the specific positions of the semiconductor substrate 20 with the well-known method. In the embodiment, the piezo resistor elements 17 are formed in the beam forming areas 16X.

In the next step, as shown in FIG. 5(B), contact holes 34 passing through the thermal oxidation layers 32 are formed with a well-known photolithography process and an etching process for electrically connecting to the piezo resistor elements 17.

In the next-step, as shown in FIG. 5(C), wirings 36 embedded in the contact holes 34 are formed on the LOCOS oxidation layers 24 and the thermal oxidation layers 32 with a well-known method. Accordingly, the piezo resistor elements 17 are electrically connected to the wirings 36. Further, the wirings 36 extend up to appropriate positions on the device, for example, positions on the frame portion 12.

In the next step, as shown in FIG. 6(A), exposed areas of the thermal oxidation layers 32 (the movable portion forming area 14X and the beam portion forming areas 16X) are removed with a well-known method. Then, as shown in FIGS. 6(B) and 6(C), passivasion layers 38 formed of, for example, silicon nitride (Si₃N₄), are formed on the semiconductor substrate 20 in areas other than the areas where the thermal oxidation layers 32 are removed. The passivasion layers 38 are patterned with a well-known lithography process and an etching process to expose the movable portion forming area 14X (described alter). Upon patterning, portions of the wirings 36 connected to the piezo resistor elements 17 may be exposed at portions of the passivasion layers 38 on the frame portion 12 to form the electrode pads 18.

In the next step, as shown in FIG. 7(A), an intermediate microstructure 13a including intermediates of the movable portion 14 and the beam portions 16 is formed. The intermediate microstructure 13a includes a microstructure supported on the sacrifice layer 22. In this step, the first silicon layer 21 at the front surface 20a of the semiconductor substrate 20 and the second silicon layer 23 at the backside surface 20b of the semiconductor substrate 20 are partially etched with the sacrifice layer 22 as an etching stopper layer to form the spaces 50 and the recess portion 15, thereby obtaining the intermediate microstructure 13a.

More specifically, a mask pattern formed of a thick resist for forming the spaces 50 is formed with a well-known lithography process such as a contact exposure process and a projection exposure process (not shown). The mask pattern is situated inside the inner circumference frame area 20d, and has openings corresponding to areas outside the movable portion forming area 14X and the beam portion forming areas 16X including the contours (outer shapes) of the constricted portions 19.

In the next step, as shown in FIG. 6(D), the first silicon layer 21 is etched from a surface of the first silicon layer 21 to a surface of the sacrifice layer or buried oxide (BOX) layer 22 with the mask pattern as a mask with a well-known method such as Bosh method. In the etching process such as an inductively coupled plasma (ICP) method, a sidewall is protected with a material such as C₄F₈, and an etchant formed of SF₆ is used. In the etching process, the sidewall protecting step and the etching step are repeated for an appropriate number of times to perform deep etching.

In the embodiment, the etching process is performed with the BOX layer 22 as an etching stopper layer. Accordingly, the BOX layer 22 is not removed in the etching process. As a result, the movable portion forming area 14X and the beam portion forming areas 16X are connected through the BOX layer 22.

When the spaces 50 are formed, the first silicon layer portion 21a in the movable portion forming area 14X; the first silicon layer portion 21b in the beam portion forming areas 16X; and the first silicon layer portion 21c in the frame portion 12 remain. That is, the constricted portions 19 are formed in the first silicon layer portion 21b in the beam portion forming areas 16X.

In the next step, as shown in FIGS. 7(A) and 7(B), the second silicon layer 23 is etched to complete the intermediate microstructure 13a unmovable including the movable portion 14 uncompleted and the beam portions 16 uncompleted.

More specifically, the semiconductor substrate 20 is inverted so that the second surface 20b faces upward. Then, a mask pattern formed of a thick resist is formed with a well-known lithography process. Then, the second silicon layer 23 is etched from the second surface 20b of the semiconductor substrate 20 with the mask pattern as a mask with a well-known method such as Bosh method. In the etching process, the second silicon layer 23 is etched inside the inner circumference frame area 20d remaining as the frame portion 12.

In this step, in the beam portion forming areas 16X, the second silicon layer 23 is etched up to the BOX layer 22 with the box layer 22 as the etching stopper layer. In the movable portion forming area 14X, the second silicon layer 23 is partially etched to form exposed surfaces (bottom surfaces) 14c.

At this moment, in the recess portion 15, there are two depths from the top surface of the frame portion 12, namely the first depth a and the second depth b. The first depth a is from the top surface of the frame portion 12 to the surface of the BOX layer 22. The second depth b is from the top surface of the frame portion 12 to the surface of the second silicon layer 23 thus etched. The movable portion 14 has a thickness c calculated by subtracting the second depth b from the first depth a. Note that the first depth a is larger than the second depth b.

In the movable portion forming area 14X, the second silicon layer portion 23a is etched to have a thickness smaller than that of the second silicon layer 23, so that the movable portion 14 has a specific movable range.

Accordingly, the recess portion 15 having the protruding portions and the recess portions is formed in the backside surface of the semiconductor substrate 20, thereby obtaining the microstructure 13a. In this state, the BOX layer 22 reinforces the first silicon layer portions 21b in the beam portion forming areas 16X. Further, the beam portion forming areas 16X are connected to the movable portion forming area 14X through the BOX layer 22. Accordingly, at this moment, the microstructure 13a is not movable.

In the next step, the microstructure 13a is converted to the microstructure 13 movable. To this end, the sacrifice layer portions 22a of the sacrifice layer (BOX layer) 22 exposed to the recess portion 15 are removed. After the sacrifice layer portions 22a are removed, the sacrifice layer portions 22b remain between the first silicon layer 21 and the second silicon layer portions 23b remaining. Accordingly, the beam portions 16 can deform to be able to measure specific acceleration. That is, at this moment, the microstructure 13 or the movable portion 14 and the beam portions 16 become movable.

In the embodiment, the manufacturing process may be adjusted according to a material of the sacrifice layer 22. It is necessary to prevent damage on the functions of the beam portions 16, the piezo resistor elements 17, and the other components.

In the embodiment, the sacrifice layer 22 is the silicon oxidation layer. Accordingly, an etchant solution may contain a mixture of acetic acid (CH₃COOH)/ammonium fluoride (NH₃F)/ammonium hydrogen fluoride (NH₄F) at a specific mixture ratio to perform a well-known wet etching process.

In the next step, the semiconductor substrate 20 is cut along dicing lines d shown in FIG. 7(A) with a well-known dicing device. As a result, as shown in FIG. 7(C), the semiconductor acceleration sensor 10 is obtained from the semiconductor substrate 20.

The disclosure of Japanese Patent Application No. 2006-150916, filed on May 31, 2006, is incorporated in the application as a reference.

While the invention has been explained with reference to the specific embodiments of the invention, the explanation is illustrative and the invention is limited only by the appended claims.

What is claimed is:

1. A micro electrical mechanical system device, comprising:
a frame portion;
a functional element;
a beam portion extending from the frame portion, said beam portion including a constricted portion; and
a movable portion supported on the beam portion and situated inside the frame portion to be movable.

2. The micro electrical mechanical system device according to claim 1, wherein said frame portion has an upper surface with a rectangular shape.

3. The micro electrical mechanical system device according to claim 1, wherein said beam portion includes a first side surface, a second side surface opposite to the first side surface, and upper and lower surfaces between the first side surface and the second side surface.

4. The micro electrical mechanical system device according to claim 3, wherein said constricted portion is formed in at least one of the first side surface and the second side surface along the functional element, said constricted portion having a main surface and two side surfaces between the upper surface and the lower surface.

5. The micro electrical mechanical system device according to claim 1, wherein said movable portion includes a center portion having four corner portions and a protruding portion extending from at least one of the four corner portions.

6. The micro electrical mechanical system device according to claim 5, wherein said protruding portion is situated away from the frame portion and the beam portion.

7. The micro electrical mechanical system device according to claim 4, wherein said constricted portion includes the two side surfaces, at least one of the two side surfaces being arranged to be perpendicular to the main surface.

8. The micro electrical mechanical system device according to claim 4, wherein said constricted portion includes the two side surfaces, at least one of the two side surfaces being connected to the main surface at a blunt angle as an inclined surface.

9. The micro electrical mechanical system device according to claim 4, wherein said constricted portion includes the two side surfaces, at least one of the two side surfaces being connected to the main surface in a curved state as a curved surface.

10. The micro electrical mechanical system device according to claim 1, wherein said functional element includes a piezo resistor element.
